(19) United States
(12) Patent Application Publication
(10) Pub. No.: US 2007/0264821 A1
(43) Pub. Date: Nov. 15, 2007

(54) Methods of forming a semiconductor device

(75) Inventors: Ju-Youn Kim, Suwon-si (KR); Seok-Jun Won, Seoul (KR); Rak-Hwan Kim, Yongin-si (KR); Min-Woo Song, Seongnam-si (KR); Weon-Hong Kim, Suwon-si (KR); Jung-Min Park, Ansan-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 11/785,305

(22) Filed: Apr. 17, 2007

(30) Foreign Application Priority Data
May 10, 2006 (KR) 10-2006-0042078

(51) Int. Cl. H01L 21/44

(52) U.S. Cl. 438/652; 438/656; 438/679; 438/681

(57) ABSTRACT

A method of forming a semiconductor device may include forming a first conductive metal compound layer on a substrate using a metal organic chemical vapor deposition (MOCVD) process and/or forming a second conductive metal compound layer on the first conductive metal compound layer using a physical vapor deposition (PVD) process. The first and second conductive metal compound layers may be formed while reducing or preventing the exposure of the first conductive metal compound layer to oxygen atoms, thus reducing degradation of the first conductive metal compound layer.

### PRIORITY STATEMENT

This application claims priority under 35 U.S.C. §119(a) to Korean Patent Application No. 10-2006-0042078, filed May 10, 2006 in the Korean Intellectual Property Office (KIPO), the entire contents of which are incorporated herein by reference.

### BACKGROUND

1. Technical Field

Example embodiments relate to methods of forming a semiconductor device having conductive metal compound layers formed by deposition processes.

2. Description of the Related Art

Semiconductor devices may employ a variety of conductive metal compound layers. For example, a titanium nitride (TiN) layer may be beneficial, because TiN is relatively non-reactive. Accordingly, a TiN layer may be employed as a barrier layer between a metal interconnection and an insulation layer. A TiN layer may also be used as an electrode in a capacitor.

A TiN layer may be formed using a metal organic chemical vapor deposition (MOCVD) process. For example, the TiN layer may be formed using a MOCVD process that employs tetrakis di-methyl amino titanium (TDMAT) as a metal organic precursor and ammonia (NH₃) as a nitrogen source. The MOCVD process may enable deposition to occur at a relatively low temperature, thus reducing or preventing the degradation of devices (e.g., MOS transistors) that may be relatively heat-sensitive. Additionally, the TiN layer formed by MOCVD may exhibit increased step coverage, even though an underlying layer may have a relatively high aspect ratio.

However, a TiN layer may contain a relatively large amount of carbon due the use of a metal organic precursor during MOCVD. Consequently, the carbon atoms in the TiN layer may react with oxygen atoms in the atmosphere, thereby degrading the TiN layer. For example, the reaction of the carbon atoms in the TiN layer with oxygen atoms may increase the electrical resistance of the TiN layer so as to result in a malfunction of the semiconductor device.

### SUMMARY OF EXAMPLE EMBODIMENTS

Example embodiments provide methods of forming a semiconductor device. The methods may include forming a first conductive metal compound layer on a substrate using a metal organic chemical vapor deposition (MOCVD) process employing a metal organic precursor and/or forming a second conductive metal compound layer on the first conductive metal compound layer using a physical vapor deposition (PVD) process. The first and second conductive metal compound layers may be maintained at sub-atmospheric pressure for the entire duration of the formation of the first and second conductive metal compound layers. The second conductive metal compound layer may also shield the first conductive metal compound layer from atmospheric exposure after formation of the first and second conductive metal compound layers.

The first and second conductive metal compound layers may be formed in a single deposition apparatus. The deposition apparatus may include a transfer chamber, a first process/deposition chamber attached to a second side of the transfer chamber, and a second process/deposition chamber attached to a third side of the transfer chamber. The first and second conductive metal compound layers may be formed in the first and second process chambers, respectively. A substrate having the first conductive metal compound layer may be moved into the second process chamber through the transfer chamber. The transfer chamber may have a pressure of about 1 atmosphere (about 760 torr) or less and may have a pressure of about 0.1 torr or less when the substrate having the first conductive metal compound layer is moved through the transfer chamber.

A plasma treatment process may be performed on the first conductive metal compound layer prior to forming the second conductive metal compound layer. The first conductive metal compound layer may have a thickness of about 200-800 Å when the plasma treatment process is performed, and the plasma treatment process may be performed at a power level of about 750 watts or less. The plasma treatment process may be performed using an in-situ process in the first process chamber and may employ hydrogen plasma, nitrogen plasma, or a combination thereof.

Before forming the first conductive metal compound layer, a lower electrode may be provided on a substrate and a dielectric layer may be provided on the lower electrode. The first conductive metal compound layer may be formed on the dielectric layer, and the second conductive metal compound layer may be formed on the first conductive metal compound layer. The first and second conductive metal compound layers may constitute an upper electrode.

The lower electrode may have a cylindrical shape, and the first conductive metal compound layer may conform to the surface profile of the lower electrode, while the second conductive metal compound layer may fill a space surrounded by the inner wall of the lower electrode. The first and second conductive metal compound layers may be made of the same or different materials, which may include titanium nitride, tantalum nitride, hafnium nitride, and/or zirconium nitride.

### BRIEF DESCRIPTION OF THE DRAWINGS

Example embodiments may be further appreciated in view of the description herein taken in conjunction with the accompanying drawings. In the drawings, the thickness of layers and regions may have been exaggerated for clarity.

FIGS. 1 to 4 are cross-sectional views illustrating a method of forming a semiconductor device according to example embodiments.

FIG. 5 is a schematic view illustrating a deposition apparatus for forming first and second conductive metal compound layers according to example embodiments.

FIG. 6 is a process flow chart illustrating a method of forming first and second conductive metal compound layers according to example embodiments.

### DETAILED DESCRIPTION OF EXAMPLE EMBODIMENTS

Example embodiments will be described below in more detail with reference to the accompanying drawings. However, example embodiments may be embodied in different forms and should not be interpreted as limited to the examples set forth herein.

It will be understood that when an element or layer is referred to as being “on”, “connected to”, “coupled to”, or “covering” another element or layer, it may be directly on, connected to, coupled to, or covering the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, third, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of example embodiments.

Spatially relative terms, e.g., “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” may encompass both an orientation of above and below. The device may be otherwise oriented (rotated 90 degrees or at other orientations) and the spatially relative descriptors used herein interpreted accordingly.

The terminology used herein is for the purpose of describing various embodiments only and is not intended to be limiting of example embodiments. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments should not be construed as limited to the shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments belong. It will be further understood that terms, including those defined in commonly used dictionaries, should be interpreted as having a meaning that is consistent with their meaning in the context of the relevant art and will not be interpreted in an idealized or overly formal sense unless expressly so defined herein.

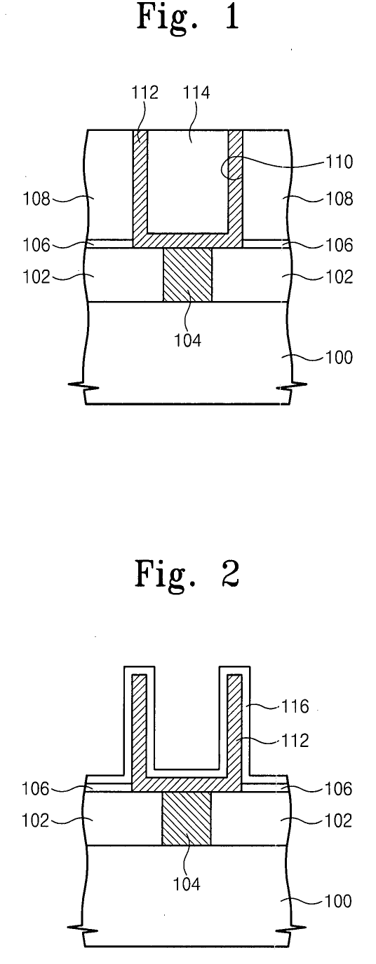

Referring to FIG. 1, an interlayer insulation layer 102 having an embedded contact plug 104 may be provided on a semiconductor substrate 100. The contact plug 104 may be made of a conductive material, and the interlayer insulation layer 102 may be made of silicon oxide. An etching stop layer 106 and a molding layer 108 may be sequentially provided on the interlayer insulation layer 102. The etching stop layer 106 may be made of an insulating material having an etching selectivity with respect to the molding layer 108. For example, if the molding layer 108 is made of silicon oxide, the etching stop layer 106 may be made of silicon nitride or a silicon oxynitride.

The molding layer 108 and the etching stop layer 106 maybe patterned to form an opening 110 that exposes the contact plug 104. A lower conductive layer (not shown), which will become the lower electrode 112, may be conformed to the molding layer 108 having the opening 110. A sacrificial layer (not shown), which will become the sacrificial pattern 114, may be provided on the lower conductive layer (not shown) so as to fill the opening 110. The sacrificial layer (not shown) and the lower conductive layer (not shown) may be planarized until the molding layer 108 is exposed. As a result, a cylindrical lower electrode 112 and a sacrificial pattern 114 may be formed in the opening 110.

The sacrificial pattern 114 may have an etching selectivity with respect to the etching stop layer 106. In addition, the sacrificial pattern 114 may have an etch rate equal to or higher than that of the molding layer 108. The sacrificial pattern 114 may include silicon oxide, and the lower electrode 112 may include a conductive material. For example, the lower electrode 112 may include at least one of a doped polysilicon, a conductive metal nitride, a noble metal, and a conductive metal oxide (e.g., an iridium oxide).

Referring to FIG. 2, the sacrificial pattern 114 and the molding layer 108 may be removed using a wet etchant to expose the lower electrode 112. The etching stop layer 106 may protect the interlayer insulation layer 102 during the removal of the sacrificial pattern 114 and the molding layer 108. A dielectric layer 116 may be conformed to the exposed surface of the lower electrode 112 so as to be of a substantially uniform thickness along the surface profile of the lower electrode 112. The dielectric layer 116 may have a higher dielectric constant than that of silicon nitride and may include at least one of an aluminum oxide, a hafnium oxide, a zirconium oxide, a titanium oxide, and a tantalum oxide. Alternatively, the dielectric layer 116 may include at least one of a silicon oxide, a silicon oxynitride, and a silicon nitride.

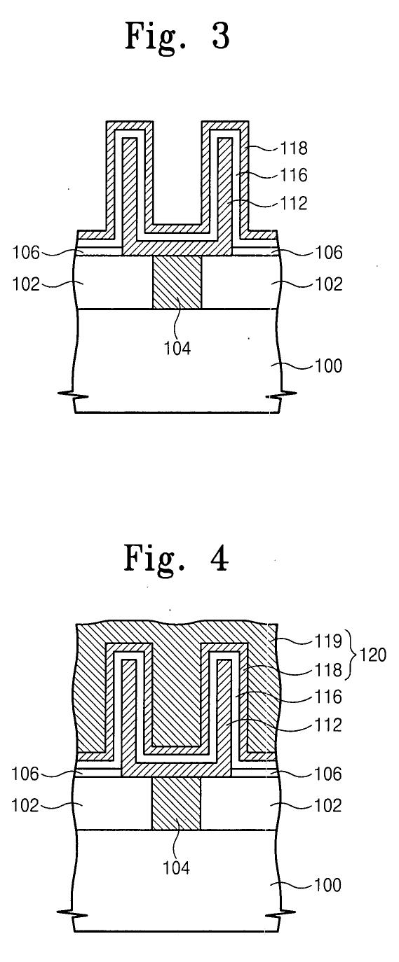

Referring to FIGS. 3 and 4, a first conductive metal compound layer 118 may be formed on the dielectric layer 116 using a metal organic chemical vapor deposition (MOCVD) process, and a second conductive metal compound layer 119 may be formed on the first conductive metal compound layer 118 using a physical vapor deposition (PVD) process. The first and second conductive metal compound layers 118 and 119 may constitute an upper electrode 120. The second conductive metal compound layer 119 may be formed while reducing or preventing the exposure of the first conductive metal compound layer 118 to the atmosphere, thus reducing the exposure of the first conductive metal compound layer 118 to oxygen atoms. For example, the entire duration of the formation of the first and second conductive metal compound layers 118 and 119, respectively, may performed in a relatively low pressure chamber and/or in a relatively low oxygen chamber to reduce exposure of the first conductive metal compound layer 118 to oxygen atoms.

Referring to FIG. 4, the lower electrode 112 may have a cylindrical shape, and the first conductive metal compound layer 118 and the dielectric layer 116 may be conformed to the surface profile of lower electrode 112. The second conductive metal compound layer 119 may be formed to fill the space surrounded by the inner wall of the lower electrode 112.

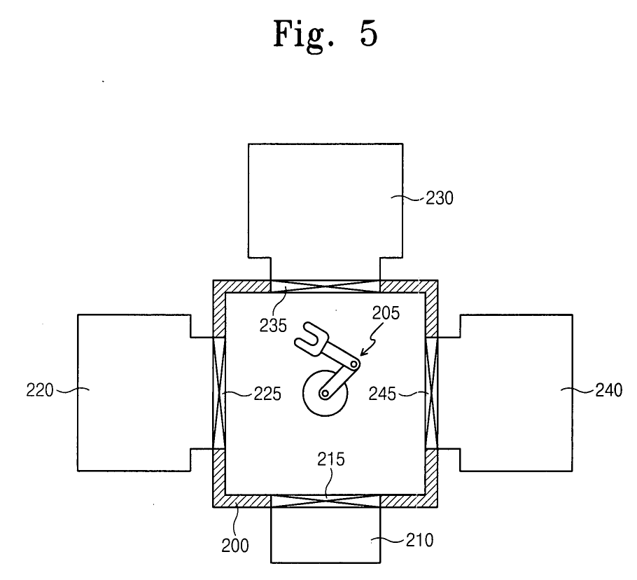

Referring to FIG. 5, a deposition apparatus may achieve and maintain sub-atmospheric pressure during processing of a semiconductor substrate (e.g., substrate 100). A substrate transfer device 205 (e.g., robot arm) may be provided in the transfer chamber 200. A substrate loading part 210 may be provided at a first side of the transfer chamber 200. The substrate loading part 210 may include a load lock chamber (not shown) for temporarily storing a semiconductor substrate to be loaded or unloaded into the transfer chamber 200. A first open/close device 215 (e.g., first gate valve) may be provided between the transfer chamber 200 and the substrate loading part 210, and the semiconductor substrate in the substrate loading part 210 may be loaded into the transfer chamber 200 through the first open/close device 215 or vice versa.

A first process chamber 220 (e.g., a first deposition chamber) may be attached to a second side of the transfer chamber 200. MOCVD may be performed in the first process chamber 220. A first chuck (not shown) and/or a shower head or gas supply conduit (not shown) for supplying source gases may be provided in the first process chamber 220. A second open/close device 225 (e.g., a second gate valve) may be provided between the transfer chamber 200 and the first process chamber 220, and a semiconductor substrate (not shown) in the transfer chamber 200 may be loaded into the first process chamber 220 through the second open/close device 225 or vice versa.

A second process chamber 230 (e.g., a second deposition chamber) may be attached to a third side of the transfer chamber 200. PVD may be performed in the second process chamber 230. A second chuck (not shown) and/or a target (not shown) may be provided in the second process chamber 230. The target (not shown) may be a metallic compound to be deposited onto the semiconductor substrate (not shown), which may be loaded on the second chuck. A third open/close device 235 (e.g., a third gate valve) may be provided between the transfer chamber 200 and the second process chamber 230, and the semiconductor substrate (not shown) in the transfer chamber 200 may be loaded into the second process chamber 230 through the third open/close device 235 or vice versa.

A third process chamber 240 may be attached to a fourth side of the transfer chamber 200. A fourth open/close device 245 (e.g., a fourth gate valve) may be provided between the transfer chamber 200 and the third process chamber 240, and the semiconductor substrate (not shown) in the transfer chamber 200 may be loaded into the third process chamber 240 through the fourth open/close device 245, or vice versa.

A variety of processes (e.g., pre/post-treatment processes) may be performed in the third process chamber 240. A pre-treatment process may be a cleaning process that is performed prior to a deposition process. A post-treatment process may be an annealing process that is performed after the deposition process. Alternatively, the cleaning process may be performed after the deposition process. The substrate transfer device 205 may transfer a semiconductor substrate (not shown) in the transfer chamber 200 into one of the substrate loading part 210, first process chamber 220, second process chamber 230, and third process chamber 240, or vice versa.

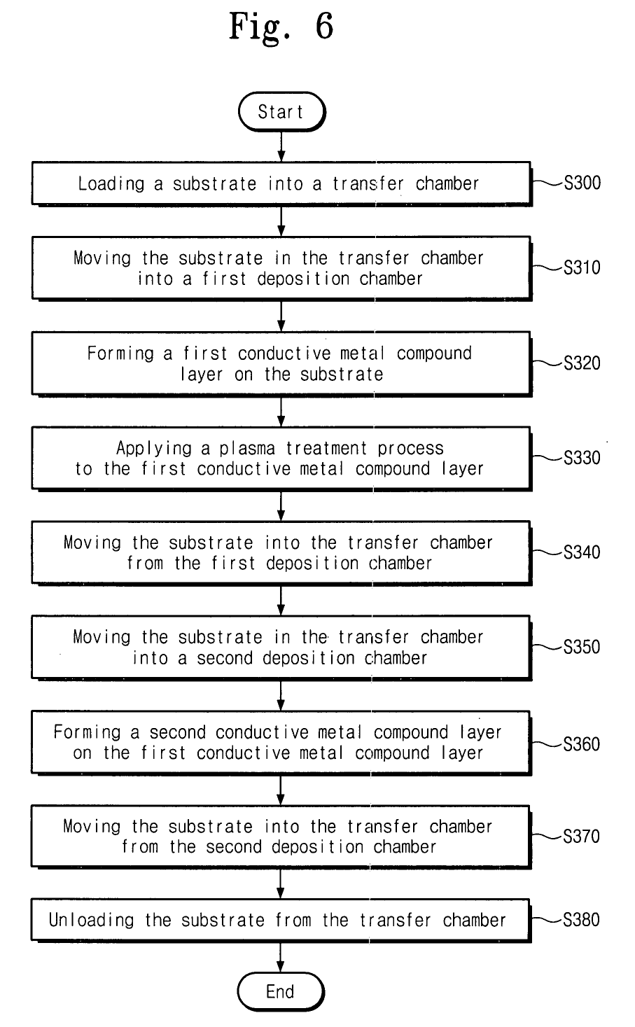

Referring to FIG. 6, the substrate 100 having the dielectric layer 116 may be loaded into the load lock chamber (not shown) of the substrate loading part 210. The load lock chamber (not shown) may isolate the substrate 100 from the outside atmosphere and may achieve sub-atmospheric pressure. The transfer chamber 200 may be brought to a pressure of about 0.1 torr or lower and when the pressure of the load lock chamber (not shown) has been decreased to be about equal to that of the transfer chamber 200, the first open/close device 215 may be opened to transfer the substrate 100 into the transfer chamber 200 (S300).

The substrate 100 in the transfer chamber 200 may be moved into first process chamber 220 (e.g., first deposition chamber) (S310). However, when a pre-treatment process is desired prior to the deposition process, the substrate 100 may be loaded into the third process chamber 240 for the pre-treatment process. After the pre-treatment process, the substrate 100 in the third process chamber 240 may be moved into the first process chamber 220 through the transfer chamber 200.

A MOCVD process may be performed on the substrate 100 in the first process chamber 220 to form a first conductive metal compound layer 11 8 on the dielectric layer 116 (S320). The first conductive metal compound layer 118 may be a first metal nitride layer. The MOCVD process may be performed using a metal organic precursor. The metal organic precursor may have an amino series and may also contain titanium, tantalum, hafnium, and/or zirconium. Additionally, the MOCVD process may be performed using a nitrogen source gas (e.g., ammonia (NH₃)). Accordingly, the first metal nitride layer may be a titanium nitride (TiN) layer, a tantalum nitride (TaN) layer, a hafnium nitride layer (HfN), and/or a zirconium nitride (ZrN) layer.

A plasma treatment process may be performed on the first conductive metal compound layer 118 prior to forming the second conductive metal compound layer 119 (S330). The plasma treatment process may be performed using an in-situ process inside the first process chamber 220 so as to reduce the potential exposure of the first conductive metal compound layer 118 to the outside atmosphere. The plasma treatment process may be performed using hydrogen plasma, nitrogen plasma, or a combination thereof.

The plasma treatment process may include purging the remaining gases in the first process chamber 220 after formation of the first conductive metal compound layer 118 prior to introducing a plasma source gas. The plasma treatment process may remove impurities (e.g., carbon atoms) in the first conductive metal compound layer 118. However, the plasma treatment may degrade the dielectric layer 116 when the first conductive metal compound layer 118 is too thin. Accordingly, the first conductive metal compound layer 118 should be of a sufficient thickness to reduce or prevent the degradation of the dielectric layer 116 during the plasma treatment process. For example, the first conductive metal compound layer 118 may have a thickness of about 200-800 Å.

Furthermore, the plasma treatment process may be performed at a relatively low power level. For example, the power level may be about 750 watts or less where the substrate is a wafer having a diameter of about 300 mm. The power level may be about 400 watts or less where the substrate is a wafer having a diameter of about 200 mm. Electric power may be used to ionize ambient gas to generate plasma.

From the first process chamber 220, the substrate 100 having the first conductive metal compound layer 118 may be moved to the transfer chamber 200 (S340). By moving the substrate 100 to the transfer chamber between processes (e.g., deposition processes), the exposure of the first conductive metal compound layer 118 to the outside atmosphere is reduced or prevented.

From the transfer chamber 200, the substrate 100 may be loaded into the second process chamber 230 (e.g., second deposition chamber) (S350), which may have a pressure of about 0.1 torr or lower, where a second conductive metal compound layer 119 may be formed on the first conductive metal compound layer 118 using a PVD process (S360). The first conductive metal compound layer 118 may act as a seed layer for the formation of the second conductive metal compound layer 119. The second conductive metal compound layer 119 may be a second metal nitride layer. The second metal nitride layer may be a titanium nitride (TiN) layer, a tantalum nitride (TaN) layer, a hafnium nitride layer (HfN), and/or a zirconium nitride (ZrN) layer. The first and second conductive metal compound layers 118 and 119, respectively, may constitute an upper electrode 120.

The second conductive metal compound layer 119 may be made of the same material as the first conductive metal compound layer 118, even though the deposition processes of the first and second conductive metal compound layers 118 and 119, respectively, may be different. For example, the first conductive metal compound layer 118 may be a MOCVD TiN layer, and the second conductive metal compound layer 119 may be a PVD TiN layer. Alternatively, the second conductive metal compound layer 119 may be made of a different material from the first conductive metal compound layer 118.

Because the first conductive metal compound layer 118 may contain carbon atoms (due to the use of a metal organic precursor during MOCVD) that may react with oxygen atoms, it may be beneficial to reduce or prevent the exposure of the first conductive metal compound layer 118 to atmospheric conditions, which may contain a relatively large amount of oxygen atoms. Accordingly, the oxygen content of the first conductive metal compound layer 118 may be reduced. Furthermore, the second conductive metal compound layer 119 may lack carbon atoms, and thus be less susceptible to reaction with oxygen atoms than the first conductive metal compound layer 118, because the second conductive metal compound layer 119 may be formed using a PVD process that does not employ a metal organic precursor. Accordingly, the second conductive metal compound layer 119 may help shield the first conductive metal compound layer 118 from oxygen atoms in the atmosphere after the substrate 100 is removed from the deposition apparatus illustrated in FIG. 5, thus reducing the degradation of the upper electrode 120.

After formation of the second conductive metal compound layer 119, the substrate 100 in the second process chamber 230 may be moved into the transfer chamber 200 (S370). From the transfer chamber 200, the substrate 100 having the upper electrode 120 may be unloaded (S380) into the substrate loading part 210 through the first open/close device 215. Where the third process chamber 240 is a post-treatment process chamber and the post-treatment process is desired after formation of the upper electrode 120, the substrate 100 having the upper electrode 120 may be moved from the transfer chamber 200 into the third process chamber 240 for the post-treatment process before unloading the substrate 100 into the substrate loading part 210.

The specification should not be construed as being limited to example embodiments described herein. For example, the first and second conductive metal compound layers 118 and 119 may be formed on lower electrodes having different configurations from the cylindrical lower electrode 112 described herein. In addition, the first and second conductive metal compound layers 118 and 119 may serve as a lower electrode for a capacitor. Furthermore, the first and second conductive metal compound layers 118 and 119 may be used in the formation of other elements (e.g., a contact plugs) of the semiconductor device.

While example embodiments have been disclosed herein, other variations may be possible. Such variations are not to be regarded as a departure from the spirit and scope of example embodiments of the present invention, and all such modifications as would be obvious to one skilled in the art are intended to be included within the scope of the following claims.

What is claimed is:

1. A method of forming a semiconductor device, comprising:
forming a first conductive metal compound layer on a substrate using a metal organic chemical vapor deposition (MOCVD) process; and
forming a second conductive metal compound layer on the first conductive metal compound layer using a physical vapor deposition (PVD) process, wherein the first and second conductive metal compound layers are maintained at sub-atmospheric pressure from the duration of the formation of the first conductive metal compound layer to the formation of the second conductive metal compound layer.

2. The method of claim 1, wherein the first and second conductive metal compound layers are formed in a single deposition apparatus,
wherein the deposition apparatus includes a transfer chamber, a first process chamber attached to a second side of the transfer chamber, and a second process chamber attached to a third side of the transfer chamber,
wherein the first and second conductive metal compound layers are formed in the first and second process chambers, respectively, and
wherein the substrate having the first conductive metal compound layer is moved into the second process chamber through the transfer chamber having sub-atmospheric pressure.

3. The method of claim 2, wherein the transfer chamber has a pressure of about 0.1 torr or less.

4. The method of claim 1, further comprising applying a plasma treatment process to the first conductive metal compound layer prior to forming the second conductive metal compound layer.

5. The method of claim 4, wherein the first conductive metal compound layer has a thickness of about 200-800 Å.

6. The method of claim 4, wherein the plasma treatment process is performed at a power level of about 750 watts or less.

7. The method of claim 4, wherein the plasma treatment process is performed using an in-situ process in the first process chamber.

8. The method of claim 4, wherein the plasma treatment process is performed using at least one of a hydrogen plasma and a nitrogen plasma.

9. The method of claim 1, further comprising:
forming a lower electrode on the substrate; and
forming a dielectric layer on the lower electrode prior to forming the first and second conductive metal compound layers, wherein the first conductive metal compound layer is formed on the dielectric layer, and the first and second conductive metal compound layers constitute an upper electrode.

10. The method of claim 9, wherein the lower electrode has a cylindrical shape and a surface profile.

11. The method of claim 10, wherein the first conductive metal compound layer is conformed to the surface profile of the lower electrode, and the second conductive metal compound layer fills a space that is surrounded by an inner wall of the lower electrode.

12. The method of claim 1, wherein the second conductive metal compound layer is made of the same material as the first conductive metal compound layer.

13. The method of claim 1., wherein the second conductive metal compound layer is made of a different material from the first conductive metal compound layer.

14. The method of claim 1, wherein the first conductive metal compound layer is a first metal nitride layer, and the second conductive metal compound layer is a second metal nitride layer.

15. The method of claim 1, wherein the MO(“VD process is performed using a metal organic precursor.

16. The method of claim 15, wherein the metal organic precursor includes an amino group.

17. The method of claim 14, wherein the first metal nitride layer is at least one of a titanium nitride, tantalum nitride, hafnium nitride, and zirconium nitride.

18. The method of claim 14, wherein the second metal nitride layer is at least one of titanium nitride, tantalum nitride, hafnium nitride, and zirconium nitride.

19. The method of claim 2, further comprising cleaning the substrate in a third process chamber prior to forming the first and second conductive metal compound layers, wherein the third process chamber is attached to a fourth side of the transfer chamber.

20. The method of claim 2, further comprising annealing the first and second conductive metal compound layers in a third process chamber, wherein the third process chamber is attached to a fourth side of the transfer chamber.
